(19) United States
(12) Patent Application Publication
(10) Pub. No.: US 2021/0018952 A1
(43) Pub. Date: Jan. 21, 2021

(54) SEMICONDUCTOR MODULE

(71) Applicant: UltraMemory Inc., Tokyo (JP)

(72) Inventors: Kazuhiko KAJIGAYA, Tokyo (JP); Takao ADACHI, Tokyo (JP)

(21) Appl. No.: 16/618,508

(22) PCT Filed: Jun. 2, 2017
(86) PCT No.: PCT/JP2017/020690

§ 371 Date: Dec. 2, 2019

(51) Int. Cl. G06F 1/02

(52) U.S. Cl. CPC G06F 1/02

(57) ABSTRACT

Provided is a semiconductor module which enables a memory bandwidth to be widened, and which enables data transfer efficiency to be improved by reducing power consumption. A semiconductor module 1 comprises: an interposer 10; and a processing unit 20 which has a plurality of processing unit main bodies 21 arrayed to be side by side with each other in a first direction F1 along the plate surface of the interposer 10, and which is placed on the interposer 10 so as to be electrically connected to the interposer 10. The processing unit main bodies 21 are provided with a plurality of subset units 22 each including: one arithmetic unit 23 including at least one core 25; and one memory unit 24 that is configured from a stacked-type RAM module and that is disposed to be side by side with the calculation unit 23 in the first direction F1. The plurality of subset units 22 are arrayed to be side by side with each other in a second direction F2 that intersects with the first direction F1.

### TECHNICAL FIELD

The present invention relates to a semiconductor module.

### BACKGROUND ART

Conventionally, volatile memories such as DRAM (Dynamic Random Access Memory) have been known as storage devices. DRAM is required to have a large capacity capable of withstanding high performance of an arithmetic unit (hereinafter referred to as a logic chip) and an increase in amount of data. Therefore, the capacity has been increased by miniaturizing a memory (memory cell array, memory chip) and increasing the number of cells in a plane. On the other hand, this type of increase in capacity has reached its limit due to the weakness to noise caused by the miniaturization, the increase in die area, and the like.

In view of this, in recent years, a technology has been developed that realizes a large capacity by stacking a plurality of planar memories to form a three-dimensional (3D) structure (for example, refer to Patent Documents 1 to 4).
Patent Document 1: Japanese Unexamined Patent Application (Translation of PCT Application), Publication No. 2016-502287
Patent Document 2: Japanese Unexamined Patent Application (Translation of PCT Application), Publication No. 2015-507372
Patent Document 3: Japanese Unexamined Patent Application (Translation of PCT Application), Publication No. 2015-502664
Patent Document 4: Japanese Unexamined Patent Application (Translation of PCT Application), Publication No. 2011-512598

### DISCLOSURE OF THE INVENTION

### Problems to be Solved by the Invention

Incidentally, with the increase in performance of the MPU and the increase in amount of data, an improvement in communication rate between the MPU and the DRAM is also required along with the increase in capacity. Although the communication rate between the MPU and the DRAM can be improved by improving the memory bandwidth, the data transfer power (consumed power) is also increased by improving the communication rate. For example, assuming the energy required to transfer one bit of data between a sense amplifier of the DRAM and a processing element of the processor is 1 pJ, the data transfer power reaches 1024 W at a memory bandwidth of 128 TB/s. Therefore, it is very useful if the memory bandwidth can be widened and the data transfer efficiency can be improved by reducing the power consumption.

It is an object of the present invention to provide a semiconductor module which can increase memory bandwidth and reduce power consumption to improve data transfer efficiency.

### Means for Solving the Problems

The present invention relates to a semiconductor module including: an interposer; and a processing unit including a plurality of processing unit main bodies arranged side by side in a first direction along a plate surface of the interposer, the processing unit being mounted on the interposer and electrically connected to the interposer, in which the processing unit main bodies each include a plurality of subset units each having one arithmetic unit including at least one core and one memory unit arranged side by side in the first direction of the arithmetic unit and configured by a stacked RAM module, and the plurality of subset units is arranged side by side in a second direction intersecting with the first direction.

Furthermore, it is preferred that the processing unit further includes a router unit that relays data communication between the plurality of processing unit main bodies and that is arranged side by side in the second direction of the processing unit main bodies.

Furthermore, it is preferred that the interposer includes a communication line that connects a plurality of router units.

Furthermore, it is preferred that the arithmetic unit includes a first interface unit at one end adjacent to the memory unit arranged side by side, and the memory unit includes a second interface unit at one end adjacent to the arithmetic unit arranged side by side.

### Effects of the Invention

According to the present invention, it is possible to provide a semiconductor module which can increase the memory bandwidth and reduce the power consumption to improve the data transfer efficiency.

### BRIEF DESCRIPTION OF THE DRAWINGS

FIG. 1 is a schematic plan view illustrating a semiconductor module according to one embodiment of the present invention;

FIG. 2 is a cross-sectional view taken along line A-A of FIG. 1;

FIG. 3 is a schematic plan view illustrating a first processing unit of a semiconductor module of one embodiment;

FIG. 4 is a schematic plan view illustrating a first processing unit and a second processing unit, and a router unit of a semiconductor module of one embodiment; and

FIG. 5 is a schematic view illustrating a length of a signal line of a semiconductor module of one embodiment.

### PREFERRED MODE FOR CARRYING OUT THE INVENTION

Hereinafter, a semiconductor module according to an embodiment of the present invention will be described with reference to the accompanying drawings. The semiconductor module 1 according to the present embodiment is, for example, a system in a package (SIP) in which an arithmetic unit (hereinafter referred to as an MPU) and a stacked DRAM are disposed on an interposer. The semiconductor module 1 is disposed on another interposer or a package substrate, and is electrically connected by using a micro bump. The semiconductor module 1 is a device that can obtain power from another interposer or package substrate, and transmit and receive data to and from another interposer or package substrate.

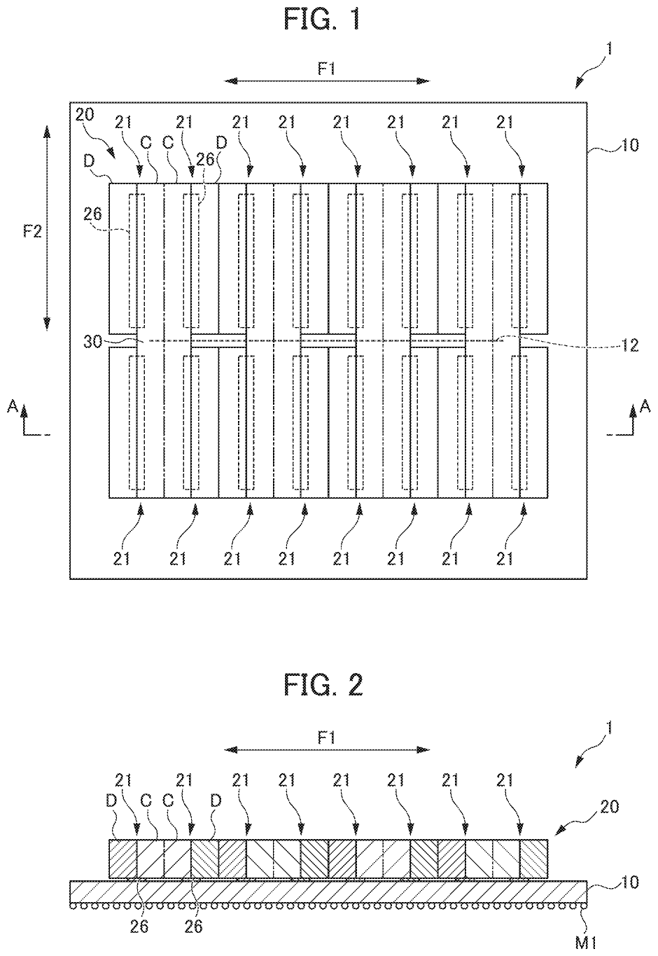

As shown in FIGS. 1 and 2, this semiconductor module 1 includes an interposer 10 and a processing unit 20. The interposer 10 is formed in a plate shape, and one surface thereof is electrically connected to another interposer or package substrate by using a bump M1. The interposer 10 has a communication line 12 connected to a plurality of router units 30, which will be described later, on the other surface thereof. The communication line 12 is disposed along the first direction F1 along the plate surface of the interposer 10. Furthermore, the interposer 10 includes a wiring unit 26 for connecting an arithmetic unit 23 described later and a memory unit 24 described later. Details of the wiring unit 26 will be described later.

The processing unit 20 is mounted on the interposer 10, and is electrically connected to the interposer 10. As shown in FIGS. 1 to 3, the processing unit 20 includes a plurality of processing unit main bodies 21 and a router unit 30.

The processing unit main body 21 is formed in a rectangular shape when viewed from the front. The processing unit main body 21 includes an arithmetic unit group C in which a plurality of arithmetic units 23 described later are arranged side by side, and a memory unit group D in which a plurality of memory units 24 described later are arranged side by side.

The arithmetic unit group C is formed in a rectangular shape when viewed from the front, and is configured by arranging the arithmetic units 23, which will be described later, along the plate surface of the interposer 10 in the second direction F2 intersecting with the first direction F1. In other words, the arithmetic unit group C is formed in a rectangular shape that is long in the second direction F2 when viewed from the front.

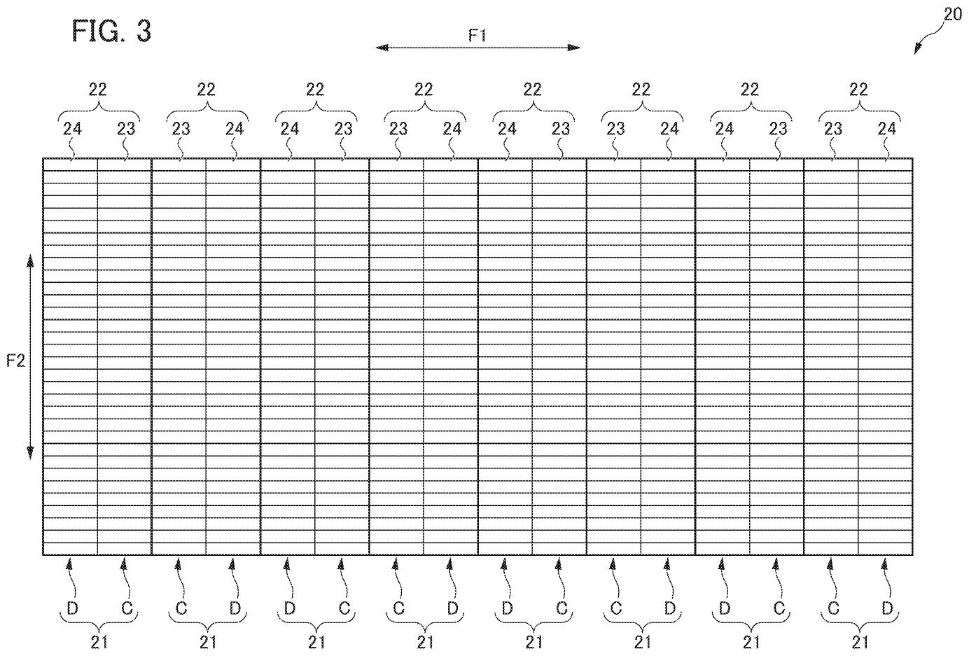

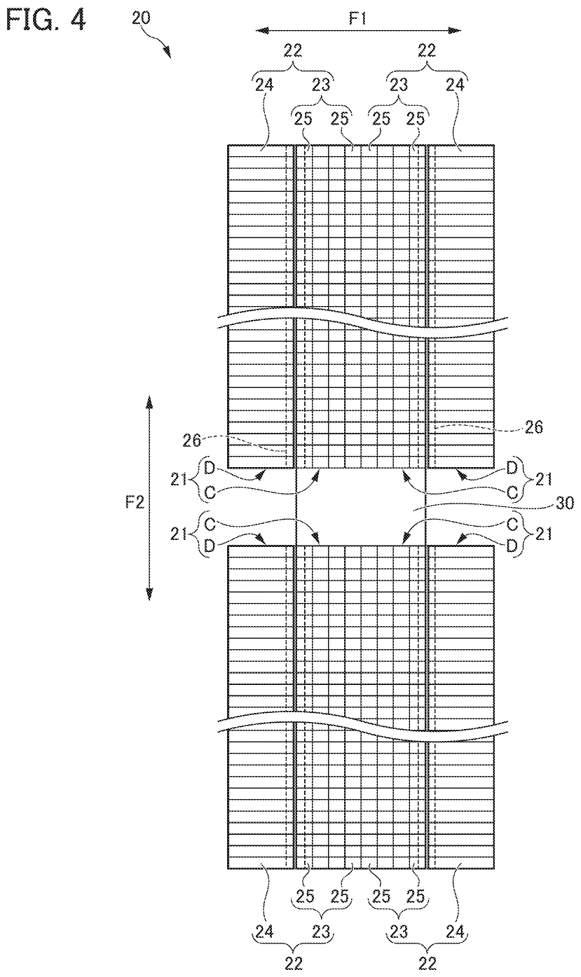

The memory unit group D is formed in a rectangular shape when viewed from the front, and the memory units 24, which will be described later, are arranged side by side in the second direction F2. In other words, the memory unit group D is formed in a rectangular shape that is long in the second direction F2 when viewed from the front. The memory unit group D is arranged side by side with the arithmetic unit group C in the first direction F1. Here, as shown in FIGS. 3 and 4, the memory units 24 configuring the memory unit group D are disposed in one-to-one correspondence with the arithmetic unit 23 configuring the arithmetic unit group C in the first direction F1. The pair of the arithmetic unit 23 and the memory unit 24 having the one-to-one correspondence configures one subset unit 22.

In the present embodiment, sixteen pieces (plural) of processing unit main bodies 21 are provided. As shown in FIG. 1, the sixteen pieces of processing unit main bodies 21 are disposed in two rows in the second direction F2, with eight pieces of processing unit main bodies 21 disposed along the first direction F1 as one column. In addition, the processing unit main bodies 21 are disposed as a set of two pieces arranged side by side in the first direction. The set of processing unit main bodies 21 are disposed in the order of the memory unit group D, the arithmetic unit group C, the arithmetic unit group C, and the memory unit group D along the first direction F1.

As shown in FIG. 3 and FIG. 4, the subset portion 22 is formed in a rectangular shape when viewed from the front. In the present embodiment, 64 pieces (plural) of subset units 22 are disposed in the second direction F2 in a single processing unit main body 21. The subset unit 22 includes one arithmetic unit and one memory unit.

The arithmetic unit 23 is formed in a rectangular shape when viewed from the front, and is disposed on the interposer 10. The arithmetic unit 23 is connected to the interposer 10 by using an ACF (anisotropic conductive film), Hybrid Bonding, a micro bump, or the like. The arithmetic unit 23 includes at least one core 25.

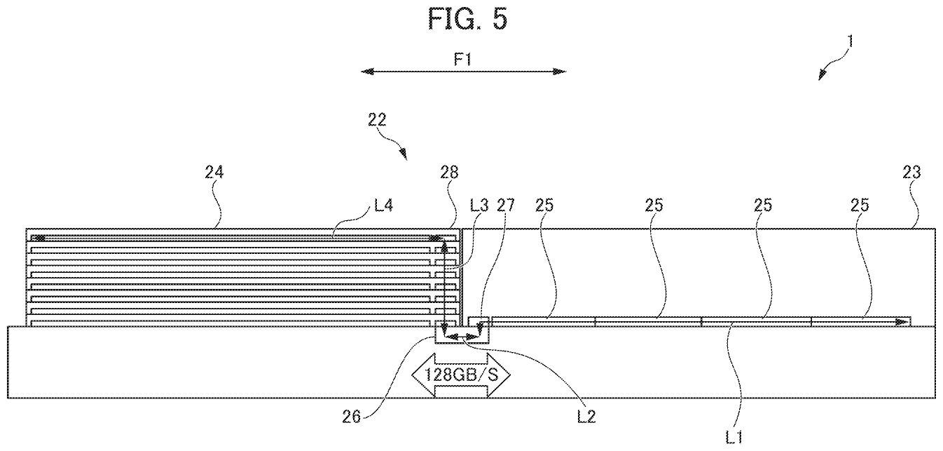

In the present embodiment, as shown in FIG. 4, the arithmetic unit 23 includes four cores 25, and the cores 25 are each arranged side by side along the first direction F1. The arithmetic unit 23 is configured to be able to communicate with the arithmetic unit 23 of the adjacent subset unit 22. In addition, the arithmetic unit 23 is disposed adjacent to the arithmetic unit 23 of the other subset unit 22 in the second direction F2. In the present embodiment, the arithmetic unit 23 is configured such that each of the four cores 25 can communicate with the other cores 25. As shown in FIG. 5, in the arithmetic unit 23, a first interface unit 27 is disposed at one end thereof adjacent to the memory unit 24 arranged side by side. The first interface unit 27 is capable of performing data communication with the memory unit 24 to be described later. As shown in FIG. 5, the arithmetic unit 23 is formed such that the length L1 in the first direction F1 is 1 mm.

The memory unit 24 is configured by a stacked RAM module, and is formed in a rectangular shape when viewed from the front. In the present embodiment, the memory unit 24 is configured by a stacked DRAM module. The memory unit 24 is disposed on the interposer 10. The memory unit 24 is connected to the interposer 10 by using an anisotropic conductive film (ACF), Hybrid Bonding, a micro bump, or the like. The memory unit 24 is arranged side by side in the first direction F1 of the arithmetic unit 23, which is one of the left and right sides along the plane of the drawing in FIG. 3. In addition, the memory unit 24 is disposed adjacent to the memory unit 24 of the other subset unit 22 in the second direction F2. As shown in FIG. 5, in the memory unit 24, the second interface unit 28 is disposed at one end thereof adjacent to the arithmetic unit 23 arranged side by side. The second interface unit 28 is capable of performing data communication with the arithmetic unit 23. As shown in FIG. 5, the memory unit 24 is formed in eight layers, for example, with a length L4 of 1 mm in the first direction F1 and an overall thickness L3 of 0.1 mm. The capacity of the memory unit 24 is 64 Mb in each layer, and it is composed of 64 MB as a whole. One subset unit 22 has an interface for one channel configured by the wiring unit 26, the first interface unit 27, and the second interface unit 28.

According to the subset unit 22 described above, the entirety of the processing unit main body 21 is configured by 256 cores 25 (256 processing elements (PEs))/cores), and has a 64-channel configuration (64 MB/channel). Each channel has a memory bandwidth of 128 GB/s by being configured with a 256 b width and a 4 Gbps communication rate, and is configured with an 8 TB/s memory bandwidth as a whole of 64 channels. In the processing unit main body 21, the capacity of the memory unit 24 is configured to be 4 GB. Since the entire module comprises 16 processing unit main bodies 21, the entire module is configured with 4096 cores 25, 1024 channels, a memory bandwidth of 128 TB/s, and the capacity of the memory unit 24 comprising 64 GB.

Furthermore, in the plurality of subset units 22, the arithmetic unit 23 and the memory unit 24 are disposed in the same order in the first direction F1, as shown in FIG. 3. That is, the arithmetic units 23 of the plurality of subset units 22 are disposed along the second direction F2, and the memory units 24 of the plurality of subset units 22 are disposed along the second direction F2. As shown in FIG. 3, the pair of processing unit main bodies 21 are disposed so that the arithmetic units 23 are adjacent to each other in the first direction F1. As a result, as shown in FIG. 3, the set of processing unit main bodies 21 are disposed in the order of the memory unit group D, the arithmetic unit group C, the arithmetic unit group C, and the memory unit group D in the first direction F1.

The router unit 30 relays data communication between the plurality of processing unit main bodies 21. The router unit 30 is connected to another router unit 30 via the communication line 12 of the interposer 10. The router unit 30 is arranged side by side in the second direction F2 of the processing unit main body 21. Specifically, the router unit 30 is arranged side by side in the second direction F2 of the arithmetic unit 23 of the processing unit main body 21. In the present embodiment, as shown in FIG. 4, one router unit 30 is provided for each set of the processing unit main bodies 21, and is disposed between the set of the processing unit main bodies 21 arranged in the second direction F2. The router unit 30 configures the arithmetic unit 23 as one arithmetic processing unit by enabling data communication of the processing unit main body 21.

Next, the wiring unit 26 will be described. The wiring unit 26 is a wiring formed on the interposer 10, and is disposed in a layered shape on the interposer 10. The wiring unit 26 electrically connects one end of the arithmetic unit 23 of the subset unit 22 with one end of the memory unit 24 in the first direction F1. In addition, a plurality of wiring units 26 is disposed in accordance with respective positions of the subset portions 22 arranged side by side in the second direction F2. In the present embodiment, the wiring unit 26 is configured by two copper pads (not shown) of 2 μm pitch and copper or aluminum wiring (not shown) of 1 μm pitch. Each of the copper pads is connected to one end of one arithmetic unit 23 and one end of one memory unit 24 in one subset unit 22, and each of both ends of the copper or aluminum wiring is connected to the two copper pads. The copper or aluminum wiring is formed with a length L2 of, for example, 0.2 mm in the first direction F1.

The above semiconductor module 1 operates as follows. As shown in FIG. 5, in one subset unit 22, the arithmetic unit 23 and the memory unit 24 are connected by the wiring unit 26 with a memory bandwidth of 128 GB/s. In one subset portion 22, the distance L1 from one end of the wiring unit 26 in the first direction F1 to the core 25 disposed at the farthest position is 1 mm. The length L2 of the wiring unit 26 along the first direction F1 is 0.2 mm. The maximum length L3 in the thickness direction of the memory unit 24 is 0.1 mm. Furthermore, the distance L4 from the second interface unit 28 to the memory block at the farthest position along the first direction F1 is 1 mm. Therefore, in one subset portion 22, the maximum wiring length is 2.3 mm.

In the semiconductor module 1 shown in FIG. 1, assuming that the memory bandwidth at the peak is 128 TB/s and the energy required to transfer 1-bit data between the sense amplifier of the DRAM and the processing element of the processor via the wiring having the largest wiring length of 2.3 mm is 0.1 pJ/b, the data transfer power at the peak of the processing unit main body 21 of one set is 6.55 W. That is, the peak data transfer power of the semiconductor module 1 is 105 W.

According to the semiconductor module 1 according to an embodiment as described above, the following effects are obtained.

(1) The semiconductor module 1 includes an interposer 10 and a processing unit 20 having a plurality of processing unit main bodies 21 arranged side by side in a first direction F1 along the plate surface of the interposer 10, and mounted on the interposer 10 and electrically connected to the interposer 10. In addition, the processing unit main body 21 includes a plurality of subset units 22 each having one arithmetic unit 23 including at least one core 25 and one memory unit 24 arranged side by side in the first direction F1 of the arithmetic unit 23 and configured by a stacked RAM module. The plurality of subset portions 22 is arranged side by side in the second direction F2 intersecting with the first direction F1. As a result, the core 25 of the arithmetic unit 23 and the memory unit 24 can be disposed close to each other, so that the connection distance therebetween can be shortened. As a result, the memory bandwidth can be widened and the power required for data communication can be reduced, so that the data transfer efficiency can be improved.

(2) The processing unit 20 further includes a router unit 30 that relays data communication between the plurality of processing unit main bodies 21 and that is arranged side by side in the second direction F2 of the processing unit main body 21. As a result, data communication between the processing unit main bodies 21 becomes possible, so that it is possible to improve the arithmetic efficiency using the plurality of subset units 22.

(3) The interposer 10 includes a communication line 12 that connects a plurality of router units 30. Since the communication line 12 is provided in the interposer 10, the router units 30 can be connected to each other without providing a separate wiring, and thus, both can be easily connected to each other.

(4) The arithmetic unit 23 includes the first interface unit 27 at one end thereof adjacent to the memory unit 24 arranged side by side, and the memory unit 24 includes the second interface unit 28 at one end thereof adjacent to the arithmetic unit 23 arranged side by side. Since the first interface unit 27 and the second interface unit 28 are disposed close to each other, the length of the signal line connecting the arithmetic unit 23 and the memory unit 24 can be further shortened.

Although the preferred embodiment of the semiconductor module of the present invention has been described above, the present invention is not limited to the above-described embodiment, and can be modified as appropriate.

For example, in the above embodiment, the combination of the stacking direction power supply connection terminal of the memory unit 24 and the stacking direction signal connection terminal of the memory unit 24 can be formed as shown in Table 1 below.

TABLE 1

| | RAM UNIT | RAM UNIT |
|---|---|---|
| | STACKING DIRECTION | STACKING DIRECTION |
| | POWER SUPLLY TERMINAL | SIGNAL LINE |
| 1 | TSV + Hybrid Bonding | TSV + Hybrid Bonding |
| 2 | ACF | ACF |
| 3 | BUMPLESS TSV | TSV + Hybrid Bonding |
| 4 | BUMPLESS TSV | ACF |

In the above embodiment, the processing unit 20 is configured by 16 pieces of the processing unit main bodies 21 in 8 rows in the first direction F1 and 2 columns in the second direction F2 in total; however, the number of the first direction F1 and the second direction F2 is not limited to this. In a case in which the plurality of processing unit main bodies 21 is disposed in the first direction F1, and one processing unit main body 21 is disposed in the second direction F2, the router unit 30 is disposed adjacent to the arithmetic unit 23 column, for each set of the processing unit main bodies 21. Furthermore, in a case in which three or more processing unit main bodies 21 are disposed in the second direction F2, the router unit 30 may be disposed adjacent to the two arithmetic unit group C between the processing unit main bodies 21 in the second direction F2. In a case in which the processing unit main body 21 is disposed as a single unit instead of a pair in the first direction F1, the router unit 30 is disposed adjacent to the arithmetic unit group C of the single processing unit main body 21. Furthermore, the router unit 30 and the arithmetic unit 23 in the processing unit main body 21 may be connected by a Network on Chip (NoC). The location of the router unit 30 may be appropriately changed, or a plurality thereof may be disposed.

In the above embodiment, the scales, the number of channels, the communication rate, the number of cores 25, the number of stacks, and the like of the arithmetic unit 23, the memory unit 24, and the wiring unit 26 are merely examples, and the present invention is not limited thereto.

In the above embodiment, the second direction F2 is a direction orthogonal to the first direction F1; however, the present invention is not limited thereto. In other words, the second direction F2 may be a direction substantially orthogonal to the first direction F1 along the plate surface of the interposer 10, or may be a direction inclined with respect to the first direction F1.

In the embodiment described above, one arithmetic unit 23 constituting the subset unit 22 and one memory unit 24 are disposed in contact with each other; however, the present invention is not limited thereto. One arithmetic unit 23 and one memory unit 24 may be disposed at predetermined intervals. In addition, in the first direction F1, the subset portions 22 may be disposed in contact with each other or may be disposed at predetermined intervals.

Furthermore, the arithmetic unit is not limited to MPUs, and may be applied to a wide range of logical chips. The memory is not limited to DRAM, and may be applied to a wide range of RAM (Random Access Memory) including nonvolatile RAM (e.g., MRAM, ReRAM, and FeRAM).

### EXPLANATION OF REFERENCE NUMERALS

1 semiconductor module
10 interposer
20 processing unit
21 processing unit main body
22 subset unit
23 arithmetic unit
24 memory unit
25 core
26 wiring unit
27 first interface unit
28 second interface unit
F1 first direction
F2 second direction

1. A semiconductor module comprising:
an interposer; and
a processing unit including a plurality of processing unit main bodies arranged in parallel in a first direction along a plate surface of the interposer, the processing unit being mounted on the interposer and electrically connected to the interposer, wherein
the processing unit main bodies each include a plurality of subset units each having one arithmetic unit including at least one core and one memory unit arranged side by side in the first direction of the arithmetic unit and configured by a stacked RAM module, and
the plurality of subset units is arranged side by side in a second direction intersecting with the first direction.

2. The semiconductor module according to claim 1, wherein the processing unit further includes a router unit that relays data communication between the plurality of processing unit main bodies and that is arranged side by side in the second direction of the processing unit main bodies.

3. The semiconductor module according to claim 2, wherein the interposer includes a communication line that connects the plurality of router units.

4. The semiconductor module according to claim 1, wherein the arithmetic unit includes a first interface unit at one end adjacent to the memory unit arranged side by side, and
the memory unit includes a second interface unit at one end adjacent to the arithmetic unit arranged side by side.
